(19) United States
(12) Patent Application Publication
(10) Pub. No.: US 2013/0037870 A1
(43) Pub. Date: Feb. 14, 2013

(54) SEMICONDUCTOR DEVICE, AND MANUFACTURING METHOD FOR SAME

(71) Applicant: Hiroaki Furukawa, Osaka (JP)

(72) Inventor: Hiroaki Furukawa, Osaka (JP)

(73) Assignee: SHARP KABUSHIKI KAISHA, Osaka (JP)

(21) Appl. No.: 13/643,389

(22) PCT Filed: Apr. 18, 2011
(86) PCT No.: PCT/JP2011/059538

§ 371 Date: Oct. 25, 2012

(30) Foreign Application Priority Data
Apr. 27, 2010 (JP) 2010-102570

(51) Int. Cl. H01L 21/20; H01L 29/78

(52) U.S. Cl. 257/288; 438/478; 257/E29.255; 257/E21.09

(57) ABSTRACT

Disclosed is a manufacturing method for a semiconductor device that prevents excessive etching of a conductive layer, even if the section where a conductive layer contact hole is formed is etched a plurality of times. A light-shielding film 20 is formed on a substrate 30. A buffer film 21, a gate insulating film 22, and a silicon film 11 are formed on the substrate 30 and the light-shielding film 20. A cleared section 40 is formed by etching to remove a section of the buffer film 21 and the gate insulating film 22, the section being on the light-shielding film 20 and disposed outside the area in which the silicon film 11 is formed. A gate electrode film 33 is formed in the cleared section 40. An inter-layer insulating film 23 is formed above the substrate 30. Etching is used to simultaneously form contact holes 45 and 46 extending to the silicon film 11 and a contact hole 44 extending to the light-shielding film 20 in the cleared section 40.

### TECHNICAL FIELD

The present invention relates to a semiconductor device having a light-shielding conductive layer, and a manufacturing method for same.

### BACKGROUND ART

A semiconductor device that has a light-shielding conductive layer on a substrate has been known since before. In such a semiconductor device, a light-shielding film located between a thin film transistor and a substrate is connected to a constant-potential power source, as disclosed in Japanese Patent Application Laid-Open Publication No. 2002-108244, for example. A manufacturing method of forming contact holes by conducting etching a plurality of times is also disclosed in Japanese Patent Application Laid-Open Publication No. 2002-108244.

### SUMMARY OF THE INVENTION

However, in the case of a configuration such as that disclosed in Japanese Patent Application Laid-Open Publication No. 2002-108244 in which contact holes are formed by conducting etching a plurality of times, the layer that the contact holes reach is etched a plurality of times. This results in a possibility that the layer that the contact holes reach is thinned out or penetrated.

In a configuration in which the potential of the light-shielding conductive layer is adjusted in order to reduce the electrical effect of parasitic capacitance present in the semiconductor device, in particular, it is necessary to connect electrically the conductive layer on the substrate to source wiring lines and the like, and therefore, etching that removes a plurality of layers needs to be conducted. That is, in forming conductive layer contact holes that extend to the conductive layer, etching is conducted a plurality of times. In such a case, there is a possibility that the conductive layer is etched excessively and thus thinned out or penetrated.

An object of the present invention is to prevent excessive etching of the conductive layer even when the parts where the conductive layer contact holes are formed are etched a plurality of times.

A manufacturing method for a semiconductor device according to one embodiment of the present invention includes: a conductive layer forming step of forming a conductive layer having a light-shielding property on a substrate; an insulating layer forming step of forming an insulating layer on the substrate and the conductive layer; an insulating layer removing step of removing a part of the insulating layer by etching to form a part where an insulating layer is removed; a gate electrode film forming step of forming a gate electrode film on the conductive layer in the part where an insulating layer is removed; an inter-layer insulating layer forming step of forming an inter-layer insulating layer above the substrate; and a contact hole forming step of forming a conductive layer contact hole by etching so as to extend from a surface of the inter-layer insulating layer to the gate electrode film in the part where an insulating layer is removed.

In the present invention, it is possible to prevent the conductive layer from being etched excessively even when the parts where the conductive layer contact holes are formed are etched a plurality of times.

### BRIEF DESCRIPTION OF THE DRAWINGS

FIG. 1 is a perspective view that shows a schematic configuration of a display panel of a liquid crystal display device provided with a semiconductor device according to Embodiment 1.

FIG. 2 is a cross-sectional view that shows a schematic configuration of the semiconductor device according to Embodiment 1.

FIG. 3A is a drawing that shows a state in which a resist pattern is formed in order to form a cleared section, in a manufacturing step of the semiconductor device according to Embodiment 1.

FIG. 3B is a drawing that shows a state in which a cleared section is formed in a manufacturing step of the semiconductor device according to Embodiment 1.

FIG. 3C is a drawing that shows a state in which gate electrode films are formed in a manufacturing step of the semiconductor device according to Embodiment 1.

FIG. 3D is a drawing that shows a state in which a resist pattern is formed in order to form contact holes in a manufacturing step of the semiconductor device according to Embodiment 1.

FIG. 3E is a drawing that shows a state in which contact holes are formed in a manufacturing step of the semiconductor device according to Embodiment 1.

FIG. 3F is a drawing that shows a state in which wiring lines, a protective film, and a transparent electrode are formed in a manufacturing step of the semiconductor device according to Embodiment 1.

FIG. 4 is a drawing that shows a different form of a gate electrode film in a cleared section.

FIG. 5 is a cross-sectional view that shows a schematic configuration of a semiconductor device according to Embodiment 2.

FIG. 6A is a drawing that shows a state in which a resist pattern is formed in order to form a cleared section in a manufacturing step of a semiconductor device according to Embodiment 2.

FIG. 6B is a drawing that shows a state in which a cleared section is formed in a manufacturing step of a semiconductor device according to Embodiment 2.

FIG. 6C is a drawing that shows a state in which a gate electrode film is formed in a manufacturing step of a semiconductor device according to Embodiment 2.

FIG. 6D is a drawing that shows a state in which a resist pattern is formed in order to form contact holes in a manufacturing step of the semiconductor device according to Embodiment 2.

FIG. 6E is a drawing that shows a state in which contact holes are formed in a manufacturing step of the semiconductor device according to Embodiment 2.

FIG. 6F is a drawing that shows a state in which wiring lines, a protective film, and a transparent electrode are formed in a manufacturing step of the semiconductor device according to Embodiment 2.

FIG. 7 is a drawing that shows a different form of a gate electrode film in a cleared section.

### DETAILED DESCRIPTION OF EMBODIMENTS

A manufacturing method for a semiconductor device according to one embodiment of the present invention includes: a conductive layer forming step of forming a conductive layer having a light-shielding property on a substrate; an insulating layer forming step of forming an insulating layer on the substrate and the conductive layer; an insulating layer removing step of removing a part of the insulating layer by etching to form a part where an insulating layer is removed; a gate electrode film forming step of forming a gate electrode film on the conductive layer in the part where an insulating layer is removed; an inter-layer insulating layer forming step of forming an inter-layer insulating layer above the substrate; and a contact hole forming step of forming a conductive layer contact hole by etching so as to extend from a surface of the inter-layer insulating layer to the gate electrode film in the part where an insulating layer is removed (first method).

According to the above method, it is possible to mitigate excessive etching of the conductive layer even when the parts where the conductive layer contact holes are formed are etched a plurality of times. In other words, it is possible to prevent the conductive layer from being etched again when the semiconductor layer contact hole and the conductive layer contact hole are formed simultaneously by etching, by forming gate electrode films on the conductive layer after removing in advance an insulating layer in the parts where the conductive layer contact holes are formed. As a result, it is possible to prevent the conductive layer from being etched a plurality of times. Therefore, it is possible to prevent the conductive layer from being thinned out or penetrated as a result of etching.

Furthermore, the gate electrode film in the part where the insulating layer is removed is formed in the same step as the gate electrode film formed on the insulating layer. Therefore, it is possible to protect the conductive layer without increasing the number of manufacturing steps of the semiconductor device.

It is preferable that the first method further include a semiconductor layer forming step of forming an island shaped semiconductor layer in the insulating layer or above the insulating layer, wherein the gate electrode film forming step includes forming the gate electrode film on the insulating layer as well as on the conductive layer in the part where an insulating film is removed, and wherein the contact hole forming step includes forming the conductive layer contact hole and a semiconductor layer contact hole that extends from a surface of the inter-layer insulating layer to the semiconductor layer simultaneously by etching (second method).

In such a configuration in which the conductive layer contact hole and the semiconductor layer contact hole that extends to the semiconductor layer are formed simultaneously by etching, more time is needed in order to etch the conductive layer contact hole because a plurality of layers need to be etched. Therefore, by removing in advance the part of the insulating film where the conductive layer contact hole is to be formed through the above-mentioned method, it is possible to prevent excessive etching of the semiconductor layer when forming the conductive layer contact hole and the semiconductor layer contact hole simultaneously by etching.

Furthermore, a gate electrode film is formed on the conductive layer in the part where the insulating film is removed, which is where the conductive layer contact hole is to be formed. Thus, even if the part where the conductive layer contact hole is to be formed is etched a plurality of times, it is possible to prevent the conductive layer from being etched a plurality of times. Therefore, it is possible to prevent the conductive layer from being thinned out or penetrated as a result of excessive etching of the conductive layer.

As a result of the above method, it is possible to prevent the conductive layer and the semiconductor layer from being etched excessively when forming the conductive layer contact hole and the semiconductor layer contact hole simultaneously by etching.

In the second method, it is preferable that the insulating layer be constituted of a buffer layer and a gate insulating layer formed on the buffer layer, that the insulating layer removing step include removing a part of the buffer layer and a part of the gate insulating layer, which are located on the conductive layer, to form the part where an insulating layer is removed, that the semiconductor layer forming step include forming the semiconductor layer on the buffer layer such that the semiconductor layer is located between the buffer layer and the gate insulating layer, and that the gate electrode film forming step include forming gate electrode films on the gate insulating layer and on the conductive layer in the part where an insulating layer is removed, respectively (third method).

In a staggered (top gate) semiconductor device obtained through this method, the inter-layer insulating film and the gate insulating film need to be etched in order for the semiconductor layer contact hole to reach the semiconductor layer. On the other hand, in the part where the conductive layer contact hole is formed, the buffer layer and the gate insulating film are each already removed, and therefore, only the inter-layer insulating film needs to be etched. Thus, if the semiconductor layer contact hole and the conductive layer contact hole are formed simultaneously by etching, the inside of the conductive layer contact hole is etched excessively.

By forming the gate electrode film in the part where the insulator is removed through the above-mentioned method, it is possible to prevent the conductive layer from being etched again when the semiconductor layer contact hole and the conductive layer contact hole are formed simultaneously by etching.

With the above-mentioned method, it is possible to prevent the conductive layer from being thinned out or penetrated as a result of excessive etching, in a staggered semiconductor device such as that mentioned above.

In the second method, it is preferable that the insulating layer be constituted of a buffer layer, that the insulating layer removing step include removing a part of the buffer layer located on the conductive layer to form the part where an insulating layer is removed, that the semiconductor layer forming step include forming a semiconductor layer on the gate insulating layer formed on the buffer layer, and that the gate electrode film forming step include forming gate electrode films on the buffer layer and the conductive layer in the part where an insulating layer is removed, respectively (fourth method).

It is also possible to prevent the conductive layer from being etched again when forming the semiconductor layer contact hole and the conductive layer contact hole simultaneously by etching by forming a gate electrode film in the part where the insulating layer is removed, in a reverse staggered (bottom gate) semiconductor device obtained through this method. Thus, with the above method, it is possible to prevent the conductive layer from being thinned out or penetrated as a result of excessive etching of the conductive layer, even in a reverse staggered semiconductor device.

A semiconductor device according to one embodiment of the present invention includes: a substrate; a conductive layer having a light-shielding property formed on the substrate; an insulating layer formed on the substrate and the conductive layer; a semiconductor layer formed in the insulating layer or above the insulating layer; an inter-layer insulating layer formed above the substrate so as to cover the insulating layer and the semiconductor layer; and wiring line members that extend through the inter-layer insulating layer towards the conductive layer and the semiconductor layer, respectively, wherein the insulating layer has a part where an insulating layer is removed in which at least a part of the insulating layer outside of a region where the semiconductor layer is formed and on the conductive layer is removed, wherein a gate electrode film and the inter-layer insulating layer are provided in the part where an insulating layer is removed, and wherein the wiring line members are provided so as to pierce the inter-layer insulating layer and extend to the gate electrode film (fifth configuration).

In the fifth configuration, it is preferable that the insulating layer be constituted of a buffer layer and a gate insulating layer formed on the buffer layer, and that the semiconductor layer be provided on the buffer layer so as to be located between the buffer layer and the gate insulating layer (sixth configuration).

In the fifth configuration, it is preferable that the insulating layer be constituted of a buffer layer, and that the semiconductor layer be provided on a gate insulating layer formed on the buffer layer (seventh configuration).

Preferred embodiments of a semiconductor device of the present invention will be described below with reference to drawings. The dimensions of the components in the drawings do not faithfully reflect the actual dimensions of the components, the ratios of the dimensions of the components, or the like.

### Embodiment 1

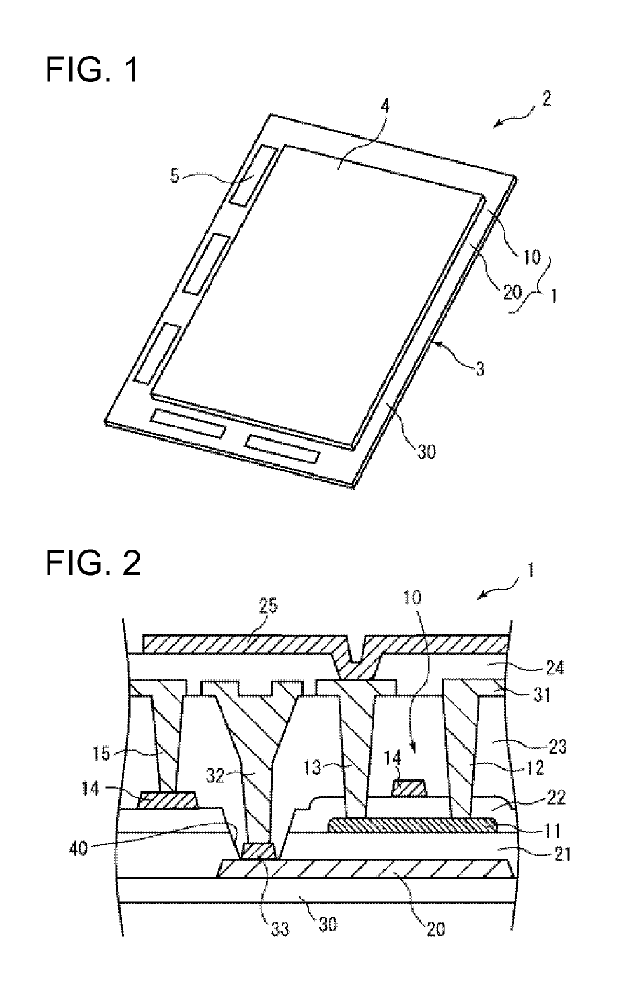

FIG. 1 shows a schematic configuration of a display panel 2 of a liquid crystal display device provided with a semiconductor device 1 according to Embodiment 1. In other words, the semiconductor device 1 of the present embodiment is used in an active matrix substrate 3 or the like that constitutes the display panel 2 of the liquid crystal display device, for example.

The display panel 2 is provided with the active matrix substrate 3, an opposite substrate 4, and a liquid crystal layer (not shown in drawings) sandwiched therebetween. The display panel 2 is illuminated by light from a backlight device, which is not shown in drawings, of the liquid crystal display device.

The active matrix substrate 3 is provided with a substrate 30 on which many pixels are arranged in a matrix form. The active matrix substrate 3 is provided with a pixel electrode and a thin film transistor (hereinafter referred to as a TFT) for each pixel. The opposite substrate 4 is provided with an opposite electrode that faces the pixel electrodes and a color filter that has a colored layer.

The liquid crystal display device controls the liquid crystals in the liquid crystal layer by driving the TFTs of the active matrix substrate 3 according to signals from drivers 5 provided in the active matrix substrate 3, thus displaying images in the display panel 2.

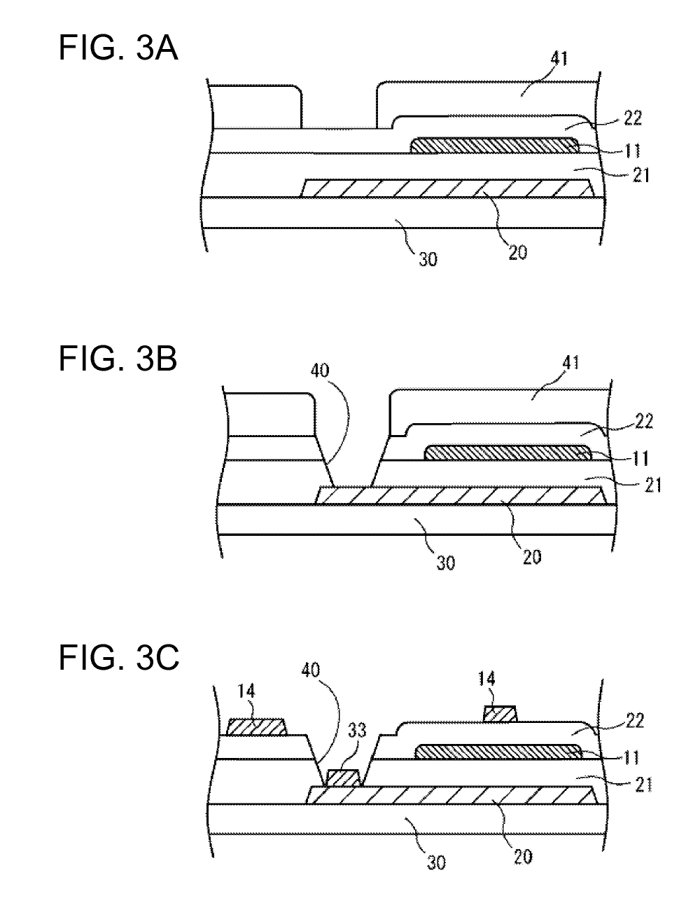

FIG. 2 shows a schematic configuration of the semiconductor device 1 according to the present embodiment. In the semiconductor device 1, a TFT 10 is formed on the substrate 30 and a light-shielding film 20 (a conductive layer having light-shielding properties) is formed between the substrate 30 and the TFT 10. The purpose of the light-shielding film 20 is to prevent illumination light from the backlight device from entering the TFT 10. The substrate 30 is a transparent glass substrate that constitutes the active matrix substrate 3, for example. In all drawings, only conductors and semiconductors are shown with a hatching pattern.

The TFT 10 is formed above the light-shielding film 20 provided on the substrate 30. In other words, the light-shielding film 20 is formed in an island shape on the substrate 30, and a buffer film 21 is formed so as to cover the substrate 30 and the light-shielding film 20. The light-shielding film 20 is made of a metallic film with tantalum (Ta), titanium (Ti), tungsten (W), molybdenum (Mo), aluminum (Al), or the like as a main component (Mo, W/TaN, MoW, Ti/Al, for example). The buffer film 21 (insulating layer, buffer layer) is made of a silicon oxide, a silicon nitride, or the like such as SiO₂/SiNO, SiO₂, or SiN.

The TFT 10 has an island-shaped silicon film 11 (semiconductor layer) formed on the buffer film 21. On the silicon film 11, a channel region and two semiconductor regions that sandwich the channel region are formed so as to be aligned in the plane direction, although this is not shown in drawings. The silicon film 11 is made of a polycrystalline silicon such as continuous grain silicon (CGS) or low-temperature polysilicon (LPS), α-Si, or the like.

Wiring lines 12 and 13 (wiring line members) are connected to the silicon film 11. The wiring line 12 is connected to a source electrode 31. The wiring line 13 is connected to a transparent electrode 25. The source electrode 31 is made of a metallic material such as Ti/Al/Ti, Ti/Al, TiN/Al/TiN, Mo/Al—Nd/Mo, or Mo/Al/Mo. The transparent electrode 25 is made of a material such as ITO or ZnO.

A gate insulating film 22 (insulating layer, gate insulating layer) is formed on the buffer film 21 so as to cover the buffer film 21 and the silicon film 11. The gate insulating film 22 is made of a silicon oxide or a silicon nitride such as SiO₂, SiN, or SiN/SiO₂. An insulating layer stated in the claims is constituted of the buffer film 21 and the gate insulating film 22.

A gate electrode film 14 of the TFT 10 is provided on the gate insulating film 22. The gate electrode film 14 is made of a metallic material such as W/TaN, Mo, MoW, or Ti/Al. The gate electrode film 14 is connected to a wiring line 15 (wiring line member). The cross-section shown in FIG. 2 does not show a state in which the gate electrode film 14 on the right is connected to the wiring line 15. However, as shown in one example on the left side of FIG. 2, the gate electrode film 14 is connected to the wiring line 15 in a different cross section from that of FIG. 2.

An inter-layer insulating film 23 (inter-layer insulating layer) is formed on the gate insulating film 22 so as to cover the gate insulating film 22 and the gate electrode film 14. A resin protective film 24 is formed on the inter-layer insulating film 23.

Outside of the region where the TFT 10 with the above-mentioned configuration is formed, a wiring line 32 (wiring line member) is electrically connected to the light-shielding film 20 via a gate electrode film 33. The gate electrode film 33 is a film formed on the light-shielding film 20 through the same process as the gate electrode film 14. The wiring line 32 is connected to the source electrode 31. The potential of the light-shielding film 20 is adjusted by the source electrode 31 via the wiring line 32 and the gate electrode film 33. Using this configuration, the potential of the light-shielding film 20 is adjusted, thus allowing the reduction of the effect of parasitic capacitance present between the TFT 10 and the light-shielding film 20.

The wiring line 32 is connected to the source electrode 31 in the present embodiment but may be connected to other wiring lines.

As shown in FIG. 2, the buffer film 21 and the gate insulating film 22 formed on the light-shielding film 20 are removed in a part that surrounds the gate electrode film 33, thus forming a cleared section 40 (part where the insulating layer is removed). The buffer film 21 and the gate insulating film 22 are not formed in the cleared section 40, and only the inter-layer insulating film 23 is formed therein. The gate electrode film 33 is formed in the cleared section 40.

(Manufacturing Method for Semiconductor Device)

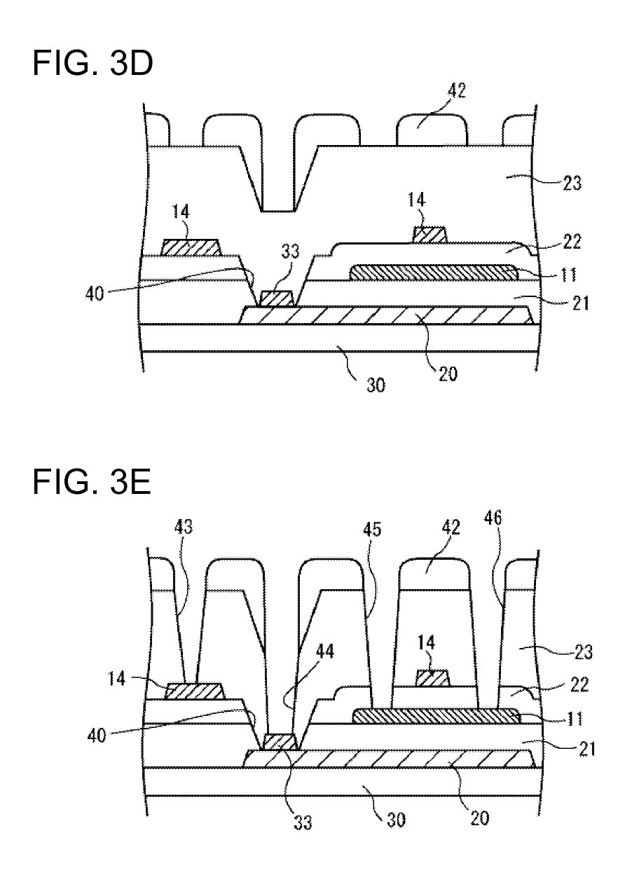

Next, a manufacturing method for the semiconductor device 1 having the above-mentioned configuration is described using FIGS. 3A to 3E. These drawings are cross-sectional views that show manufacturing steps of the semiconductor device 1 according to the present embodiment.

First, as shown in FIG. 3A, a light-shielding film 20 is formed on the substrate 30 so as to prevent illumination light from a backlight device from entering the TFT 10 from one side (lower side in the drawing) of the substrate 30.

Specifically, first, a light-shielding thin film of approximately 30 nm to 300 nm in thickness is formed on one surface of the substrate 30 (upper surface in the drawing) by the chemical vapor deposition (CVD) method, the sputtering method, or the like. After that, using the photolithography method, a resist pattern is formed so as to cover the region where the light-shielding film 20 is to be formed, and the light-shielding thin film is etched using the resist pattern as a mask. As a result, the light-shielding film 20 is formed. In the present embodiment, the light-shielding film 20 is made of Mo, for example.

Next, the buffer film 21 is formed so as to cover the substrate 30 and the light-shielding film 20. The buffer film 21 is made of a laminated film of SiNO/SiO₂, for example. The buffer film 21 is formed by the CVD method so as to be approximately 100 nm to 400 nm in thickness.

Next, a silicon thin film made of CGS, for example, is formed by the CVD method on the buffer film 21. The silicon thin film is formed so as to be 30 nm to 100 nm in thickness. After that, using the photolithography method, a resist pattern is formed so as to cover a region where the silicon film 11 is to be formed, and the silicon thin film is etched using the resist pattern as a mask. As a result, the silicon film 11 is formed. The silicon film 11 is doped by ion implantation or the like, and a source region and a drain region (not shown in drawings) are formed therein.

A gate insulating film 22 made of SiO₂, for example, is formed on the buffer film 21 and the silicon film 11 by the CVD method. The gate insulating film 22 is formed so as to be 50 nm to 200 nm in thickness.

A resist pattern 41 is formed on the gate insulating film 22 above the light-shielding film 20 so as to have an opening in a part other than the region where the silicon film 11 is formed. In other words, the resist pattern 41 has an opening that exposes the region where the cleared section 40 is to be formed in the gate insulating film 22.

Next, as shown in FIG. 3B, the gate insulating film 22 and the buffer film 21 are etched using the resist pattern 41 as a mask. The gate insulating film 22 and the buffer film 21 are etched until the light-shielding film 20 is exposed. As a result, the gate insulating film 22 and the buffer film 21 located above a part of the light-shielding film 20 are removed, thus forming the cleared section 40.

Here, the etching in FIG. 3B is conducted by dry etching using an etching gas (C₄F₈, SF₆, CF₄, O₂, Ar, H₂, or the like). Alternatively, wet etching that uses buffered hydrogen fluoride (BHF) or the like may be conducted. A method that combines wet etching and dry etching may also be used. The etching conducted in FIG. 3B may also be of a type that does not etch the light-shielding film 20.

Then, the resist pattern 41 is removed and a metallic film made of W/TaN, for example, is formed on the gate insulating film 22 by the sputtering method. The metallic film is formed so as to be 200 nm to 500 nm in thickness. By photolithography, a resist pattern is formed so as to cover regions where the gate electrode films 14 and 33 are to be formed, and using the resist pattern as a mask, the metallic film is etched. As a result, the gate electrode films 14 and 33 are formed, as shown in FIG. 3C. The gate electrode films 14 are formed on the gate insulating film 22. The gate electrode film 33 is formed on the light-shielding film 20 in the cleared section 40.

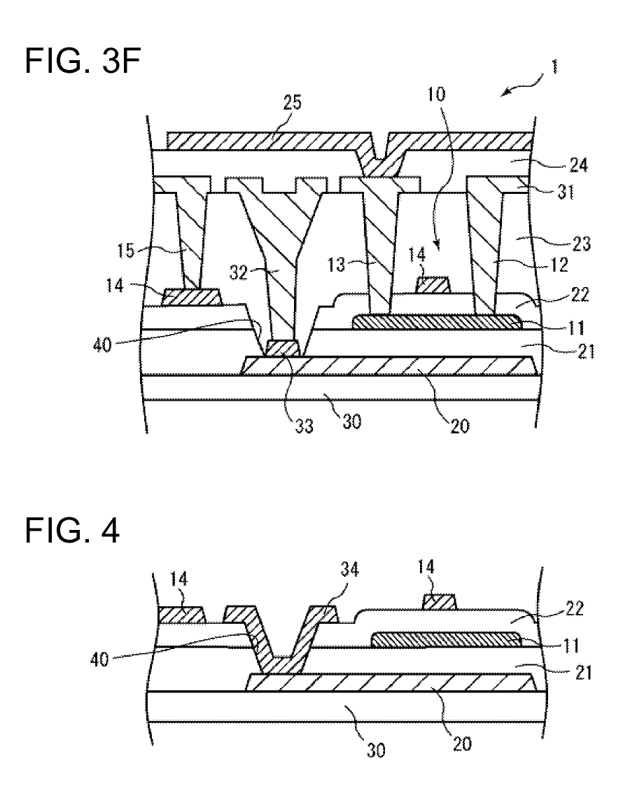

As shown in FIG. 4, a gate electrode film 34 that is not only in the cleared section 40 but extends from inside the cleared section 40 onto the gate insulating film 22 may be formed.

Next, as shown in FIG. 3D, the inter-layer insulating film 23 made of a laminated film of SiO₂/SiN, for example, is formed on the gate insulating film 22, the gate electrode films 14, and the cleared section 40, by the CVD method. After that, a resist pattern 42 is formed on the inter-layer insulating film 23. The resist pattern 42 has openings that expose the regions where the contact holes 43 to 46 are to be formed, which are where the wiring lines 15, 32, 13, and 12 are to be formed.

As shown in FIG. 3E, the regions where the contact holes 45 and 46 (semiconductor layer contact holes) are to be formed, which are where the wiring lines 13 and 12 are to be formed, are located on the silicon film 11 in a plan view (the view from the upper side of the drawing). The region where the contact hole 43 (gate electrode contact hole) is to be formed, which is where the wiring line 15 is to be formed, is located on the gate electrode film 14 in a plan view (the view from the upper side of the drawing). The region where the contact hole 44 (conductive layer contact hole) is to be formed, which is where the wiring line 32 is to be formed, is located on the gate electrode film 33 in the cleared section 40 in a plan view (the view from the upper side of the drawing).

Next, as shown in FIG. 3E, the inter-layer insulating film 23 and the gate insulating film 22 are etched using the resist pattern 42 as a mask. As a result, contact holes 43 to 46 are formed so as to extend from the surface of the inter-layer insulating film 23 to the gate electrode film 14, the gate electrode film 33, and the silicon film 11, respectively. It is preferable that the etching conducted be dry etching using etching gas. Wet etching may be conducted after the majority of the etching is done by dry etching instead of conducting all etching by dry etching.

In the region where the contact hole 44 is to be formed, which is where the wiring line 32 is to be formed, the buffer film 21 and the gate insulating film 22 are removed, and only the inter-layer insulating film 23 is formed. Thus, the thickness of the films where etching is needed is the greatest in the regions where the contact holes 45 and 46 for the wiring lines 13 and 12 connected to the silicon film 11 are to be formed. In other words, in the regions where the contact holes 43 and 44 for the wiring lines 15 and 32 are to be formed, only the inter-layer insulating film 23 needs to be etched, whereas in the regions where the contact holes 45 and 46 for the wiring lines 13 and 12 are to be formed, the inter-layer insulating film 23 and the gate insulating film 22 need to be etched. Therefore, the amount of time needed to etch the region where the contact holes 45 and 46 are to be formed can serve as a benchmark when the regions where the contact holes 43 to 46 are to be formed are etched simultaneously. Thus, during the etching shown in FIG. 3E, the silicon film 11 can be prevented from being etched excessively. In addition, in the regions where the contact holes 43 and 44 for the wiring lines 15 and 32 are to be formed, the inter-layer insulating film 23 has approximately the same thickness in both regions. Therefore, when the regions where the contact holes 43 and 44 are to be formed are etched simultaneously, the gate electrode film 14 can be prevented from being etched excessively.

Furthermore, by providing the gate electrode film 33 in the region where the contact hole 44 for the wiring line 32 is formed as in the present embodiment, it is possible to prevent the light-shielding film 20 in that region from being etched excessively. In other words, the light-shielding film 20 undergoes etching again when the contact hole 44 is formed after being etched when the cleared section 40 is formed as stated above, thus increasing the susceptibility of the light-shielding film 20 to being thinned out. By providing a gate electrode film 33 in the part where the light-shielding film 20 is etched as stated above, the light-shielding film 20 can be protected from the etching that takes place when the contact hole 44 is being formed. Therefore, it is possible to prevent the light-shielding film 20 from being thinned out or penetrated as a result of etching.

After removing the resist pattern 42, wiring lines 15, 32, 13, and 12 are formed in the contact holes 43 to 46 as shown in FIG. 3F, and a source electrode 31 is also formed. Also, a protective film 24 and a transparent electrode 25 are formed on the inter-layer insulating film 23. As a result, the semiconductor device 1 is formed.

Here, the step of forming the light-shielding film 20 on the substrate 30 corresponds to the conductive layer forming step, and the step of forming the buffer film 21 and the gate insulating film 22 on the substrate 30 and the light-shielding film 20 corresponds to the insulating layer forming step. The step of forming a silicon film 11 on the buffer film 21 corresponds to the semiconductor layer forming step, and the step of forming the gate electrode films 14 and 33 on the gate insulating film 22 and in the cleared section 40 corresponds to the gate electrode film forming step.

Also, the step of removing the buffer film 21 and the gate insulating film 22 located above a part of the light-shielding film 20 to form the cleared section 40 corresponds to the insulating layer removing step, and the step of forming an inter-layer insulating layer 23 corresponds to the inter-layer insulating layer forming step. The step of forming the contact holes 43 to 46 corresponds to the contact hole forming step.

(Effects of Embodiment 1)

In the present embodiment, the cleared section 40 was formed by etching a part of the buffer film 21 and the gate insulating film 22 on the light-shielding film 20, which is connected to the wiring line 32. Then, the gate electrode film 33 was formed in the cleared section 40 in the same step in which the gate electrode film 14 was formed. Then the regions where the plurality of contact holes 43 to 46 were to be formed were etched simultaneously. Thus, the light-shielding film 20 can be prevented from being thinned out or penetrated when simultaneously etching the regions where the plurality of contact holes 43 to 46 are to be formed. In other words, according to the configuration of the present embodiment, when simultaneously etching the regions where the plurality of contact holes 43 to 46 are to be formed, the gate electrode film 33 provided on the light-shielding film 20 is etched instead of the light-shielding film 20, in the contact hole 44. Therefore, it is possible to prevent the light-shielding film 20 from being thinned out or penetrated as a result of being etched twice.

In addition, as described above, the gate electrode film 33 in the cleared section 40 is formed in the step of forming the gate electrode film 14 of the TFT 10. Thus, the light-shielding film 20 can be protected from excessive etching without increasing the number of steps in the manufacturing process of the semiconductor device 1.

In the region where the contact hole 44 for the wiring line 32 is to be formed, the buffer film 21 and the gate insulating film 22 are removed in advance. Thus, there is no need to etch the buffer film 21 and the gate insulating film 22 when forming the contact hole 44. Therefore, the amount of time taken for etching is decreased. Thus, when simultaneously etching the regions where the plurality of contact holes 43 to 46 are to be formed, the silicon film 11 can be prevented from being etched excessively in the regions where the contact holes 45 and 46 for the wiring lines 13 and 12 are formed.

In particular, the TFT 10 of the present embodiment is the so-called top gate TFT in which the silicon film 11 is located between the buffer film 21 and the gate insulating film 22, and the gate electrode film 14 is formed on the gate insulating film 22. Thus, the thickness of the films to be etched is the greatest in the regions where the contact holes 45 and 46 are formed, which are where the wiring lines 13 and 12 are connected to the silicon film 11. Therefore, it is possible to etch the regions where the contact holes 43 and 44 are to be formed within the time required to etch the regions where the contact holes 45 and 46 are to be formed. As a result, it is possible to reliably prevent the silicon film 11 from being thinned out or penetrated due to etching.

The inter-layer insulating film 23 to be etched in the region where the contact hole 43 for the wiring line 15 connected to the gate electrode film 14 is to be formed has approximately the same thickness as that of the inter-layer insulating film 23 in the region where the contact hole 44 for the wiring line 32 connected to the light-shielding film 20 is to be formed. Thus, when simultaneously etching the regions where the plurality of contact holes 43 to 46 are to be etched, it is possible to prevent the gate electrode film 14 from being etched excessively.

### Embodiment 2

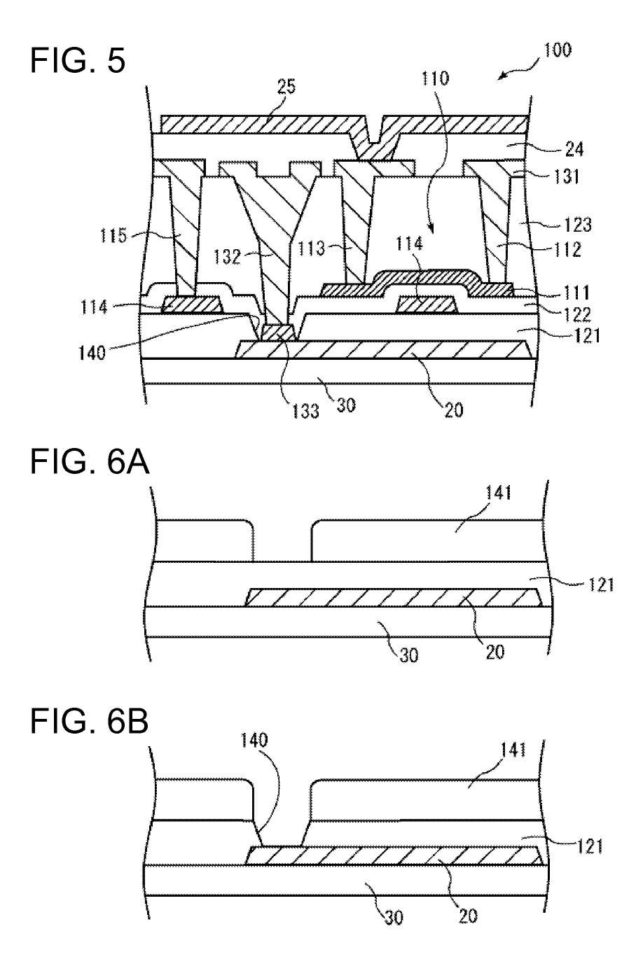

FIG. 5 shows a schematic configuration of a semiconductor device 100 according to Embodiment 2. In the present embodiment, the configuration of a TFT 110 differs from that of Embodiment 1. In the description below, configurations that are the same as those of Embodiment 1 are given the same reference characters, and only parts that differ will be described.

Specifically, the TFT 110 of the present embodiment is the so-called bottom gate TFT in which a silicon film 111 (semiconductor layer) is formed on a gate insulating film 122 (insulating layer, gate insulating layer), and a gate electrode film 114 is formed between a buffer film 121 (insulating layer, buffer layer) and the gate insulating film 122.

A gate electrode film 133, which electrically connects a wiring line 132 (wiring line member) to a light-shielding film 20, is provided in a cleared section 140 (a part where an insulating layer is removed) where the buffer film 121 is removed. In other words, the cleared section 140, where the buffer film 121 is removed, is formed so as to surround the gate electrode film 133. In the cleared section 140, the gate insulating film 122 and the inter-layer insulating film 123 are provided.

With this configuration, when regions where contact holes 143 to 146 for wiring lines 115, 132, 113, and 112 are to be formed are etched simultaneously, it is possible to reduce the etching time for the region where the contact hole 144 for the wiring line 132 is to be formed, as in Embodiment 1.

Furthermore, according to the above configuration, the light-shielding film 20 is not etched, whereas the gate electrode film 133 is etched, during the second etching that occurs in the region where the contact hole 144 for the wiring line 132 is to be formed, as in Embodiment 1. Thus, the light-shielding film 20 can be prevented from being thinned out or penetrated by being etched excessively.

(Manufacturing Method for Semiconductor Device)

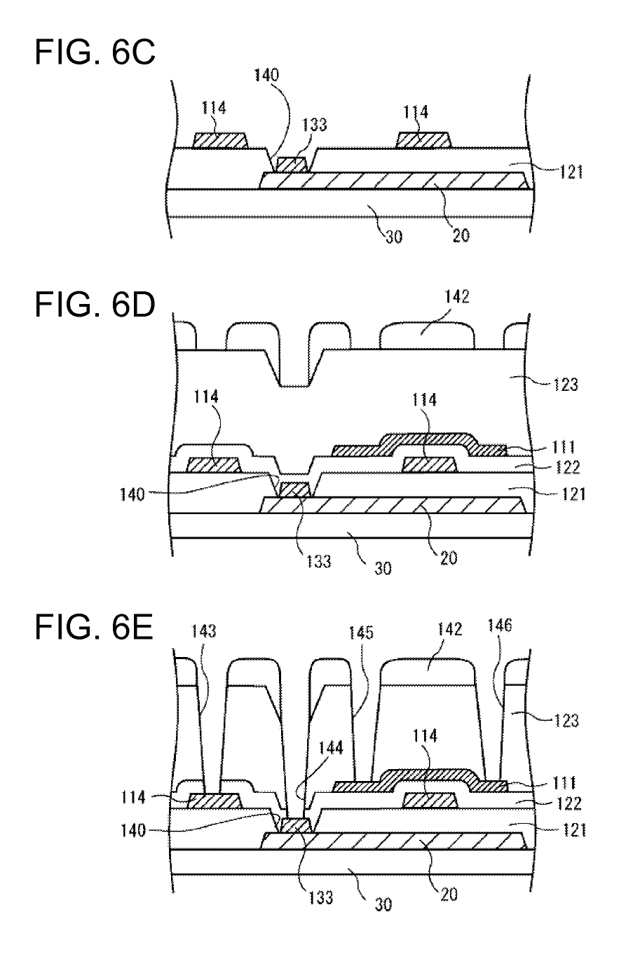

Next, a manufacturing method for the semiconductor device 100 of Embodiment 2 will be described using FIGS. 6A to 6E, mainly where different from Embodiment 1. These drawings are cross-sectional views that show manufacturing steps of the semiconductor device 100 of the present embodiment. The materials and the like of the films that constitute the semiconductor device 100 are the same as those of Embodiment 1.

First, a light-shielding film 20 is formed on a substrate 30 so as to prevent illumination light of a backlight device from entering the TFT 110 from one side of the substrate 30 (lower side in drawing) as in Embodiment 1, as shown in FIG. 6A. After that, a buffer film 121 is formed so as to cover the substrate 30 and the light-shielding film 20.

Next, by the photolithography method, a resist pattern 141 is formed on the buffer film 121 so as to have an opening above the light-shielding film 20 in a part other than the region where the silicon film 111 is to be formed. In other words, the resist pattern 141 has an opening that exposes the region where the cleared section 140 is to be formed in the buffer film 121.

As shown in FIG. 6B, the buffer film 121 is etched using the resist pattern 141 as a mask. The buffer film 121 is etched until the light-shielding film 20 is exposed. As a result, the buffer film 121 located above a part of the light-shielding film 20 is removed, thus forming the cleared section 140.

The etching that takes place in FIG. 6B may be wet etching or dry etching, as in Embodiment 1. Alternatively, a method that combines wet etching and dry etching may be used.

Next, after the resist pattern 141 is removed, a metallic film is formed on the buffer film 121 and the cleared section 140 by the sputtering method. After that, by the photolithography method, a resist pattern is formed so as to cover the regions where the gate electrode films 114 and 133 are to be formed, and the metallic film is etched using the resist pattern as a mask. As a result, gate electrode films 114 and 133 are formed as shown in FIG. 6C. The gate electrode films 114 are formed on the buffer film 121. The gate electrode film 133 is formed on the light-shielding film 20 in the cleared section 140.

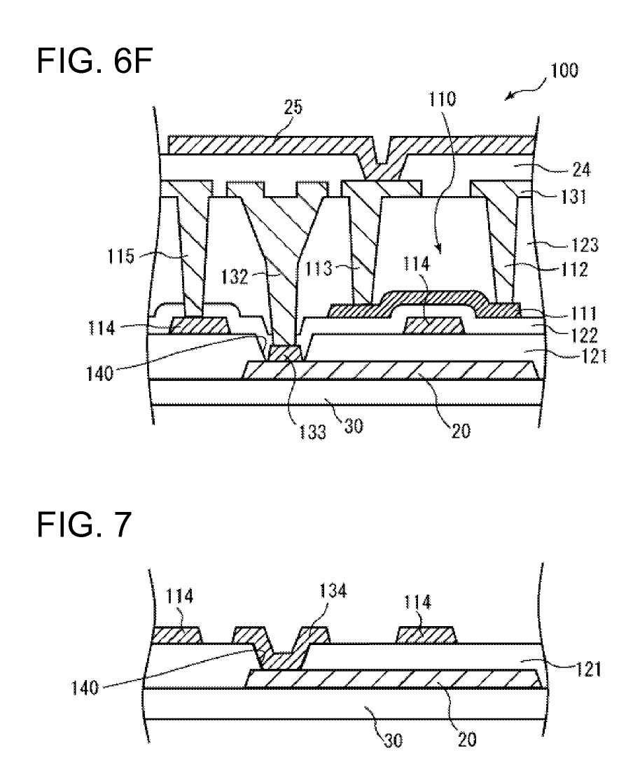

As shown in FIG. 7, a gate electrode film 134 may be formed not only in the cleared section 140 but so as to extend from the cleared section 140 onto the buffer film 121, as in Embodiment 1.

As shown in FIG. 6D, a gate insulating film 122 similar to that of Embodiment 1 is formed on the buffer film 121 and the gate electrode films 114 by the CVD method. A silicon thin film is formed by the CVD method on the gate insulating film 122. After that, by the photolithography method, a resist pattern is formed so as to cover the region where the silicon film 111 is to be formed, and the silicon thin film is etched using the resist pattern as a mask. As a result, the silicon film 111 is formed.

The inter-layer insulating film 123 is formed on the gate insulating film 122 and the silicon film 111 by the CVD method. After that, a resist pattern 142 is formed on the inter-layer insulating film 123 so as to have openings in regions where the contact holes 143 to 146 are to be formed, which is where the wiring lines 115, 132, 113, and 112 are formed.

As shown in FIG. 6E, the regions where the contact holes 145 and 146 (semiconductor layer contact holes) are to be formed, which is where the wiring lines 113 and 112 are formed, are located on the silicon film 111 in a plan view (the view from the upper part of the drawing). The region where the contact hole 143 (gate electrode contact hole) is to be formed, which is where the wiring line 115 is formed, is located on the gate electrode film 114 in a plan view (the view from the upper part of the drawing). The region where the contact hole 144 (conductive layer contact hole) is to be formed, which is where the wiring line 132 is formed, is located on the gate electrode film 133 in the cleared section 140 in a plan view (the view from the upper part of the drawing).

Next, as shown in FIG. 6E, the inter-layer insulating film 123 and the gate insulating film 122 are etched using the resist pattern 142 as a mask. As a result, from the surface of the inter-layer insulating film 123, contact holes 143 to 146 that extend to the gate electrode film 114, the gate electrode film 133, and the silicon film 111, respectively, are formed. The etching at this time is preferably dry etching using an etching gas. It is not necessary to conduct all etching by dry etching, and wet etching may be conducted after the majority of etching is done by dry etching.

In the region where the contact hole 144 for the wiring line 132 is to be formed, the buffer film 121 is removed; thus, the gate insulating film 122 and the inter-layer insulating film 123 are formed in this region. Therefore, the thickness of the films to be etched is approximately the same between the region where the contact hole 144 for the wiring line 132 is to be formed and the regions where the contact holes 145 and 146 for the wiring lines 113 and 112, which are connected to the silicon film 111, are to be formed. Therefore, it is possible to prevent the silicon film 111 from being etched excessively when etching as shown in FIG. 6E.

Furthermore, in the region where the contact hole 144 for the wiring line 132 is to be formed, a gate electrode film 133 is formed on the light-shielding film 20. Thus, when forming the plurality of contact holes 143 to 146 simultaneously by etching, the gate electrode film 133 is etched instead of the light-shielding film 20. Therefore, it is possible to prevent the light-shielding film 20 from being thinned out or penetrated by being etched excessively.

After the resist pattern 142 is removed, the wiring lines 115, 132, 113, and 112 are formed in the contact holes 143 to 146 along with the source electrode 131, as shown in FIG. 6F. A protective film 24 and a transparent electrode 25 are formed on the inter-layer insulating film 123. Thus, the TFT 110 is formed.

The step of forming the light-shielding film 20 on the substrate 30 corresponds to the conductive layer forming step, and the step of forming the buffer film 121 on the substrate 30 and the light-shielding film 20 corresponds to the insulating layer forming step. The step of forming the silicon film 111 on the gate insulating film 122 corresponds to the semiconductor layer forming step, and the step of forming the gate electrode films 114 and 133 on the buffer film 121 and in the cleared section 140 corresponds to the gate electrode film forming step.

The step of removing the buffer film 121 located above a part of the light-shielding film 20 to form the cleared section 140 corresponds to the insulating layer removing step, and the step of forming the inter-layer insulating layer 123 corresponds to the inter-layer insulating layer forming step. The step of forming the contact holes 143 to 146 corresponds to the contact hole forming step.

(Effects of Embodiment 2)

In the present embodiment, after etching the buffer film 121 on the light-shielding film 20, which is connected to the wiring line 132, and forming the cleared section 140, the gate electrode film 133 was formed in the cleared section 140 in the same step in which the gate electrode films 114 were formed. After the inter-layer insulating film 123 was formed, the regions where the plurality of contact holes 143 to 146 were to be formed were etched simultaneously. As a result, in the region where the contact hole 144 for the wiring line 132 is to be formed, the gate electrode film 133 is etched instead of the light-shielding film 20, and thus, the light-shielding film 20 can be prevented from being etched excessively. Therefore, the light-shielding film 20 can be prevented from being thinned out or penetrated as a result of etching.

As described above, the gate electrode film 133 in the cleared section 140 is formed in the step in which the gate electrode films 114 of the TFT 110 are formed. As a result, the light-shielding film 20 can be protected from excessive etching without increasing the number of manufacturing steps of the semiconductor device 100.

Also, the configuration of the present embodiment allows the films etched in the region where the contact hole 144 is to be formed to be made equally thick as those of the regions where the contact holes 145 and 146 for the wiring lines 113 and 112 connected to the silicon film 111 are to be formed. Therefore, when simultaneously etching the regions where the plurality of contact holes 143 to 146 are to be formed, the silicon film 111 in the regions where the contact holes 145 and 146 are to be formed can be prevented from being etched excessively.

### Other Embodiments

Embodiments of the present invention have been described above, but the above embodiments are mere examples of implementations of the present invention. The present invention is not limited to the above embodiments, and can be implemented by appropriately modifying the above embodiments without departing from the spirit thereof.

In the aforementioned embodiments, contact holes 44 and 144, which extend to the light-shielding layer 20, are formed at the same time as contact holes 43, 45, 46, 143, 145, and 146, by etching. However, as long as the contact holes 44 and 144 are etched a plurality of times, the contact holes 44 and 144 do not need to be formed at the same time as other contact holes. Also, the configurations of the semiconductor devices 1 and 100 are not limited to those of the aforementioned embodiments, and other configurations may be used.

In the aforementioned embodiments, a semiconductor device having a three-terminal semiconductor element (TFT) was shown as an example. However, the configuration of Embodiment 1 may be applied to a semiconductor device having a two-terminal semiconductor element (a photodiode, for example). An example of a semiconductor device having a two-terminal semiconductor element is a semiconductor device in which Embodiment 1 is applied but the gate electrode film 14 is omitted and the silicon film 11 is formed as a PN diode or a PIN diode. This diode is applicable as a photosensor, for example.

### INDUSTRIAL APPLICABILITY

The semiconductor device according to the present invention is applicable as a semiconductor device in which wiring lines are connected to a light-shielding film such that the potential of the light-shielding film can be adjusted.

1. A manufacturing method for a semiconductor device, comprising:
a conductive layer forming step of forming a conductive layer having a light-shielding property on a substrate;
an insulating layer forming step of forming an insulating layer on the substrate and the conductive layer;
an insulating layer removing step of removing a part of the insulating layer by etching to form an area where an insulating layer is removed;
a gate electrode film forming step of forming a gate electrode film on the conductive layer in the area where an insulating layer is removed;
an inter-layer insulating layer forming step of forming an inter-layer insulating layer above the substrate; and
a contact hole forming step of forming a conductive layer contact hole by etching so as to extend from a surface of the inter-layer insulating layer to the gate electrode film in the area where an insulating layer is removed.

2. The manufacturing method for a semiconductor device according to claim 1, further comprising a semiconductor layer forming step of forming an island shaped semiconductor layer in the insulating layer or above the insulating layer,
wherein the gate electrode film forming step includes forming the gate electrode film on the insulating layer as well as on the conductive layer in the area where an insulating film is removed, and
wherein the contact hole forming step includes forming the conductive layer contact hole and a semiconductor layer contact hole that extends from a surface of the inter-layer insulating layer to the semiconductor layer simultaneously by etching.

3. The manufacturing method for a semiconductor device according to claim 2,
wherein the insulating layer is constituted of a buffer layer and a gate insulating layer formed on the buffer layer,
wherein the insulating layer removing step includes removing a part of the buffer layer and a part of the gate insulating layer, which are located on the conductive layer, to form the area where an insulating layer is removed,
wherein the semiconductor layer forming step includes forming the semiconductor layer on the buffer layer such that the semiconductor layer is located between the buffer layer and the gate insulating layer, and
wherein the gate electrode film forming step includes forming gate electrode films on the gate insulating layer and on the conductive layer in the area where an insulating layer is removed, respectively.

4. The manufacturing method for a semiconductor device according to claim 2,
wherein the insulating layer is constituted of a buffer layer,
wherein the insulating layer removing step includes removing a part of the buffer layer located on the conductive layer to form the area where an insulating layer is removed,
wherein the semiconductor layer forming step includes forming a semiconductor layer on the gate insulating layer formed on the buffer layer, and
wherein the gate electrode film forming step includes forming gate electrode films on the buffer layer and on the conductive layer in the area where an insulating layer is removed, respectively.

5. A semiconductor device, comprising:
a substrate;
a conductive layer having a light-shielding property formed on the substrate;
an insulating layer formed on the substrate and the conductive layer;
a semiconductor layer formed in the insulating layer or above the insulating layer;
an inter-layer insulating layer formed above the substrate so as to cover the insulating layer and the semiconductor layer; and
wiring line members that extend through the inter-layer insulating layer towards the conductive layer and the semiconductor layer, respectively,
wherein the insulating layer has an area in which at least a part of the insulating layer outside of a region where the semiconductor layer is formed and on the conductive layer is removed,
wherein a gate electrode film and the inter-layer insulating layer are provided in the area where an insulating layer is removed, and
wherein the wiring line members are provided so as to pierce the inter-layer insulating layer and extend to the gate electrode film.

6. The semiconductor device according to claim 5,
wherein the insulating layer is constituted of a buffer layer and a gate insulating layer formed on the buffer layer, and
wherein the semiconductor layer is provided on the buffer layer so as to be located between the buffer layer and the gate insulating layer.

7. The semiconductor device according to claim 5,
wherein the insulating layer is constituted of a buffer layer, and
wherein the semiconductor layer is provided on a gate insulating layer formed on the buffer layer.
